(19) United States
(12) Patent Application Publication
(10) Pub. No.: US 2025/0081575 A1
(43) Pub. Date: Mar. 6, 2025

(54) SEMICONDUCTOR COMPONENT AND METHOD FOR PRODUCING A SEMICONDUCTOR COMPONENT

(71) Applicant: Robert Bosch GmbH, Stuttgart (DE)

(72) Inventors: Kevin Dannecker, Reutlingen (DE); Dick Scholten, Stuttgart (DE); Jens Baringhaus, Sindelfingen (DE)

(21) Appl. No.: 18/824,548

(22) Filed: Sep. 4, 2024

(30) Foreign Application Priority Data
Sep. 6, 2023 (DE) 10 2023 208 583.6

(51) Int. Cl. H01L 29/40; H01L 23/31; H01L 29/66; H01L 29/78

(52) U.S. Cl. CPC H10D 64/111; H01L 23/3171; H01L 23/3185; H10D 30/0291; H10D 30/665; H10D 64/01

(57) ABSTRACT

A semiconductor component with a semiconductor substrate. The semiconductor component has at least one source element, at least one drain element, and at least one field plate. In the semiconductor component, the at least one field plate encloses an edge of the semiconductor component and is electrically contacted with the drain element. A method for producing a semiconductor component is also described.

### FIELD

The present invention relates to a semiconductor component, preferably a power MOSFET element, and to a method for producing a semiconductor component.

### BACKGROUND INFORMATION

An essential part of a semiconductor component, for example a power transistor, is the component periphery. In this region, high field strengths can arise due to the breaking of symmetry. For this reason, a so-called peripheral structure or peripheral shielding is generally provided. Various possibilities for shielding are described in the related art; for example, B. Baliga. “Fundamentals of Power Semiconductor Devices;” Springer US, 2008, doi:10.1007/978-0-387-47314-7 describes various variants. Nevertheless, the periphery of the component continues to be a vulnerable region. Electrical breakdown can occur, which generally destroys the component. If, however, the periphery is well enough protected, the breakdown takes place in the cell field and there ideally through the so-called avalanche breakdown in the drift zone. This is not destructive, provided the component is avalanche-capable (e.g., a GaN trench MOSFET).

Another approach to reducing field peaks is to provide a field plate. This overhang, usually made of metal, facilitates the distribution of the potential drop over a larger region and thus reduces the field strength.

Field plates and their use in semiconductor components are generally conventional in the related art. They are elements, that are electrically isolated from the active semiconductor region and are generally elements short-circuited to the source electrode and made of a conductive material, for example metal or polysilicon. The field plate is generally arranged in direct spatial proximity to the drift zone. It is used to reduce peaks in the electric field at the periphery of the component and at junctions between the n-doped drift zone and other p-doped regions, such as peripheral structures or the channel region, in order to compensate for the charge in the drift zone and influences the charge carrier concentrations in the drift zone through its doping. It makes higher doping in the drift zone possible, which reduces the resistance of the component in the switched-on state, but at the same time maintains a high breakdown voltage, which is necessary for safe operation of the semiconductor component.

### SUMMARY

According to the present invention, a semiconductor component with a semiconductor substrate is provided, wherein the semiconductor component has at least one source element, at least one drain element and at least one field plate. In the semiconductor component according to an example embodiment of the present invention, the at least one field plate encloses an edge of the semiconductor component and is electrically contacted with the drain element.

The present invention thus relates to a new type of design of a field plate, which ensures, specifically at the periphery of the component or at the component edge, a more favorable field distribution with regard to avoiding electrical breakdowns. As a result, the advantageous material parameters, such as the high critical field strength, can be better utilized, especially in so-called wide-bandgap semiconductors.

In contrast to the usual approach, the field plate is not at the source potential, but at the drain potential. As a result, the field distribution in the semiconductor and specifically at the component edge can be better influenced. This reduces the probability of breakdown in this region and reduces the load on the passivation layer, which in turn has a positive effect on the service life of the component.

The semiconductor component may, for example, be a MOSFET (metal-oxide semiconductor field-effect transistor). The semiconductor substrate may, for example, be silicon, another semiconductor substrate or a silicon-on-insulator (SOI) substrate.

In a preferred embodiment of the present invention, the semiconductor component may have a vertical structure. Here, the source element is formed on a first surface of the semiconductor component, and the drain element is formed on a second surface, wherein the second surface is opposite to the first surface. The field plate comprises a first portion and a second portion connected to the first region, wherein the first region is formed on the first surface of the semiconductor component, and the second region extends along a peripheral region of the semiconductor component and is contacted with the drain element. In other words, the field plate has a substantially L-shaped cross-section. The angle between the first portion and the second portion may, for example, be approximately 90° or more than 90°.

The field plate can be contacted with the drain element via the highly doped layer of the semiconductor substrate and/or via a metallization of the drain element.

In a preferred embodiment of the present invention, a passivation layer is formed on a surface of the semiconductor component that is assigned to the source element and on an edge of the semiconductor component such that the passivation layer encloses the edge of the semiconductor component. The field plate is formed on the passivation layer.

According to an example embodiment of the present invention, particularly preferably, at least one doped peripheral structure is formed in the region of the first surface, wherein the doping of the region differs in particular from the doping of the semiconductor substrate, and wherein the first region of the field plate on the surface extends to the periphery of the doped region. This doped peripheral structure can additionally influence the field distribution. The doped peripheral structure preferably has a doping gradient such that the doping decreases toward the periphery of the semiconductor component.

In this case, a passivation layer can be formed on the first surface such that the thickness of the passivation layer increases in a region starting from the edge of the semiconductor component to the periphery of the doped region and the first region of the field plate is formed on the region of the passivation layer in which the thickness of the passivation layer increases. This measure favorably influences the field distribution.

In a preferred embodiment of the present invention, the semiconductor component comprises a plurality of in each case parallel-connected source elements, drain elements and gate elements along with a plurality of field plates.

According to an example embodiment of the present invention, particularly preferably, the semiconductor component is designed as a power transistor, in particular as a power MOSFET element.

According to a further aspect of the present invention, a method for producing a semiconductor component designed according to the present invention is provided. According to an example embodiment of the present invention, the method comprises the following steps:
a. etching a semiconductor substrate down to a highly doped layer of the semiconductor substrate in the region of the drain element during the production of a periphery of the semiconductor component,
b. depositing a passivation layer at least on a surface of the semiconductor component that is assigned to a source element and on the periphery of the semiconductor component,
c. applying a field plate to the passivation layer such that the field plate encloses an edge of the semiconductor component and is connected to the drain element in a low-resistance manner by means of the highly doped layer.

The field plate can preferably be applied during a source metallization.

A so-called contact metallization can additionally be deposited between the drain element and the field plate material. This contact metallization can preferably be deposited and structured together with the contact metallization of the source element.

The present invention efficiently and cost-effectively provides a semiconductor component that is protected against electrical breakdowns in the peripheral region of the component and can thus have improved service life and reliability.

### BRIEF DESCRIPTION OF THE DRAWINGS

Exemplary embodiments of the present invention are explained in more detail with reference to the figures and the following description.

FIGS. 1A to 1C show, in each case, a section through a semiconductor component from the related art.

FIG. 2 shows a section through a semiconductor component according to a first example embodiment of the present invention.

FIG. 3 shows a section through a semiconductor component according to a second example embodiment of the present invention.

where only one peripheral region of the semiconductor component is shown in each case.

### DETAILED DESCRIPTION OF EXAMPLE EMBODIMENTS

In the following description of the exemplary embodiments of the present invention, identical elements are denoted by the same reference signs, and repeated description of these elements may be omitted if necessary. The figures show the subject matter of the present invention only schematically.

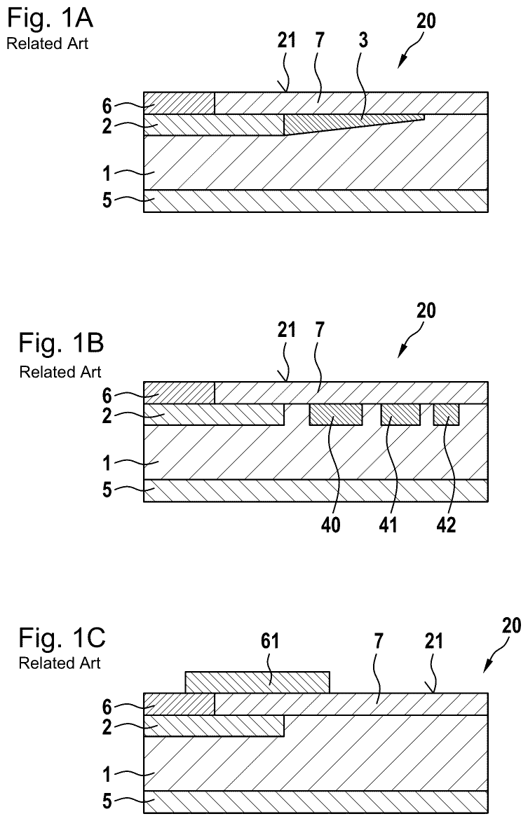

FIG. 1A shows a section through the peripheral region of a semiconductor component 20 according to the related art. In this example, the semiconductor component 20 comprises an n-doped semiconductor 1 with a p-doped region 2 in order to create a blocking junction. The regions are contacted by the contact 5 of the drain region 15 and the contact 6 of the source region 16. In addition, a passivation layer 7, for example an oxide layer, is located on the surface 21 assigned to the source element 6. Various measures to reduce field peaks are described in the related art. In the example according to FIG. 1A, a p-doped peripheral structure with a doping gradient is located below the passivation layer 7.

Alternatively, it is conventional, as shown in FIG. 1B, to provide so-called guard rings 40, 41, 42 below the passivation layer 7 in order to reduce field peaks. In this example, these guard rings 40, 41, 42 are formed as ring-shaped, p-doped regions on the surface 21 at the periphery of the semiconductor component 20.

Furthermore, it is conventional, as shown in FIG. 1C, to provide one or more field plates 61 above the passivation 7 in order to reduce field peaks, said field plates being conductively connected to the source region 2, for example via the source contact 6. This overhang, usually made of metal, facilitates the distribution of the potential drop over a larger spatial region and thus reduces the field strength.

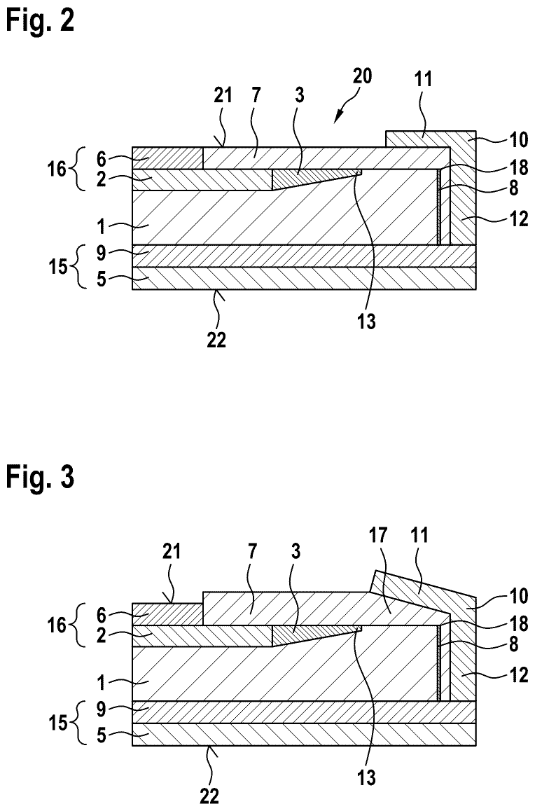

FIG. 2 shows a section through the peripheral region of a semiconductor component 20 according to a first exemplary embodiment of the present invention.

In this example, the semiconductor component 20 comprises an n-doped semiconductor 1. A p-doped region 2 is formed on a first surface 21 and, together with a source contact 6, forms a source element 16 of the semiconductor component 20. In the region of a second surface 22, which is opposite to the first surface 21, a highly n-doped semiconductor layer 9 is formed, which is covered by a metallic layer, the drain contact 5. The highly n-doped semiconductor layer 9 and the drain contact 5 form the drain element 15 of the semiconductor component 20. Adjacent to the source contact 6, a passivation layer 7 is located on the surface 21 assigned to the source element 16. The semiconductor component 20 furthermore comprises a p-doped peripheral structure 3 with a doping gradient.

Etching down to the highly n-doped layer 9 in the region of the drain contact 5 takes place during the production of the periphery 8 of the semiconductor component 20, the so-called mesa edge. After the passivation layer 7 has been deposited, a field plate 10, which encloses the edge 18 of the semiconductor component 20, is also produced during the source metallization. The field plate 10 is connected to the drain contact 5 in a low-resistance manner via the highly doped semiconductor 9 and, separated from the passivation layer 7, covers the periphery 8 of the semiconductor component 20. The field plate 10 comprises a first portion 11, which extends substantially in parallel with the first surface 21 of the semiconductor component 20. The field plate 10 extends around the edge 18 of the semiconductor component 20 and comprises a second portion 12, which extends along the periphery 8 of the semiconductor component 20 and is contacted with the drain element 15. On the front side of the semiconductor component 20, the field plate 10 bends and thus encloses the edge 18 of the semiconductor component 20. The first portion 11 of the field plate extends, for example, approximately to the outer periphery 13 of the p-doped peripheral structure 3 of the semiconductor component 20. As a result, the drain potential is advantageously impressed on all semiconductor regions next to and below the field plate 10, and the potential profile toward the p-doped peripheral structure 3 can be influenced by the overhang of the field plate and the thickness of the passivation layer 7.

FIG. 3 shows a section through the peripheral region of a semiconductor component 20 according to a second exemplary embodiment of the present invention. In contrast to the variant according to FIG. 2, the semiconductor component 20 comprises a passivation layer 7, which, on the surface 21 assigned to the source element 16, in the region of the edge 18, has a region 17 with increasing thickness starting from the periphery 8. The region 17, in which the thickness of the passivation layer 7 increases, approximately ends with the outer periphery 13 of the p-doped peripheral structure 3. The first portion 11 of the field plate 10 is formed on the region 17. In this example, the angle between the first portion 11 and the second portion 12 of the field plate is thus more than 90°.

The effectiveness of the field plate, or its compensating influence on the electric field in the semiconductor and at the junction from the semiconductor to the passivation, inter alia depends significantly on the spatial distance. The embodiment shown here increases the effect of the field plate toward the periphery continuously and depending on the angle (steeper=faster). As a result, there is an additional degree of freedom in order to optimize the field distribution.

1-9. (canceled)

10. A semiconductor component, comprising:
a semiconductor substrate, including at least one source element, at least one drain element, and at least one field plate, the at least one field plate encloses an edge of the semiconductor component, and the field plate is electrically contacted with the drain element.

11. The semiconductor component according to claim 10, wherein the semiconductor component has a vertical structure, wherein the source element is formed on a first surface of the semiconductor component and the drain element is formed on a second surface, wherein the second surface is opposite to the first surface, and wherein the field plate includes a first portion and a second portion connected to the first region, wherein the first region is formed on the first surface of the semiconductor component and the second region extends along a periphery of the semiconductor component and is contacted with the drain element.

12. The semiconductor component according to claim 10, wherein the field plate is contacted with the drain element via a highly doped layer of the semiconductor substrate and/or of a drain metallization.

13. The semiconductor component according to claim 10, wherein at least one passivation layer is formed on a first surface of the semiconductor component that is assigned to the source element and on a periphery of the semiconductor component, wherein the field plate is formed on the passivation layer.

14. The semiconductor component according to claim 11, wherein, in a region of the first surface, at least one doped peripheral structure is formed in the semiconductor substrate, wherein a doping of the peripheral structure differs in particular from a doping of the semiconductor substrate, and wherein the first region of the field plate on the first surface extends to an outer periphery of the doped peripheral structure.

15. The semiconductor component according to claim 14, wherein a thickness of a passivation on the first surface increases in a region starting from the edge of the semiconductor component to the periphery of the doped region and the first region of the field plate is formed on the region of the passivation.

16. The semiconductor component according to claim 10, wherein the semiconductor component includes a plurality of in each case parallel-connected source elements, drain elements and gate elements along with a plurality of field plates.

17. The semiconductor component according to claim 11, wherein the semiconductor component is a power transistor including a power MOSFET element.

18. A method for producing a semiconductor component, comprising the following steps:
a. etching a semiconductor substrate down to a highly doped layer of the semiconductor substrate in a region of a drain element during production of a periphery Of the semiconductor component with an edge;
b. depositing a passivation layer at least on a surface of the semiconductor component that is assigned to a source element and on a periphery of the semiconductor component; and
c. applying, during a source metallization, a field plate to the passivation layer such that the field plate encloses an edge of the semiconductor component and is connected to the drain element in a low-resistance manner using the highly doped layer.
